(19) United States
(12) Patent Application Publication
(10) Pub. No.: US 2012/0017982 A1
(43) Pub. Date: Jan. 26, 2012

(54) Thin Film Silicon Solar Cell and Manufacturing Method Thereof

(75) Inventors: Kuang-Chieh Lai, Taichung City (TW); Fu-Ji Tsai, Taichung City (TW); Jen-Hung Wang, Taichung City (TW)

(73) Assignee: NEXPOWER TECHNOLOGY CORPORATION, Taichung City (TW)

(21) Appl. No.: 13/187,869

(22) Filed: Jul. 21, 2011

(30) Foreign Application Priority Data
Jul. 21, 2010 (TW) 099123935

(51) Int. Cl. H01L 31/0232; H01L 31/18; H01L 31/0224

(52) U.S. Cl. 136/256; 438/71; 257/E31.13

(57) ABSTRACT

A thin film silicon solar cell and a manufacturing method thereof. The thin film silicon solar cell comprises a glass substrate, a first electrode layer, a light absorbing layer, a second electrode layer, and a metal electrode layer sequentially stacked on top of one another. The second electrode layer has a texture surface and concavities formed on the texture surface, and each of the concavities has a width falling within a range of 100 nm-1600 nm and a depth less than 800 nm.

### FIELD OF THE INVENTION

The present invention relates to a thin film silicon solar cell and a manufacturing method thereof, in particular to the thin film silicon solar cell having a glass substrate, and the manufacturing method thereof

### BACKGROUND OF THE INVENTION

Due to the world's energy shortage, governments and private sectors pay increasingly more attention to the application of solar cells, because solar energy is an everlasting resource and the power generation process causes no environmental pollution issues. Therefore, solar energy has become a popular alternative energy source and led to a blooming industry of solar cells. Among a variety of solar cell technologies, thin film solar cells have the advantages of using less silicon material, providing a high total power generation, and integrating with construction materials easily, so that the thin film solar cells attract much attention.

At present, most thin film silicon solar cells with a glass substrate adopts a superstrate structure. In the superstrate structure, a transparent conductive oxide (TCO) layer is coated onto a glass substrate, and then three P-I-N silicon thin film layers (also known as light absorbing layers) are coated sequentially, and finally a metal layer is coated, so that an incident light can be passed from the glass substrate into the solar cell. Since the bottom layer of the thin film silicon solar cell with the superstrate structure is made of metal, the metal reflective layer will reflect a major fraction of the incident light back to the absorbing layer for a reuse of the light energy if the incident light has not been absorbed completely by the light absorbing layer. However, the metal layer generally has a poor surface adhesion with silicon, and if the metal layer is deposited directly on the silicon, defects occurred at the junction between the metal layer and silicon will give rise to a light absorption, and the light will be unable to reflect back to the absorbing layer effectively. In general, a TCO layer is usually formed between the metal layer and silicon to improve the reflectivity of the light and the stability of the components.

Therefore, the thin film silicon solar cell with the superstrate structure requires upper and lower TCO layers, wherein the TCO layer proximate to the incident light is called a front TCO layer, and the other TCO layer is called a back TCO layer. For a flat surface, the incident light can enter and exit the thin film silicon solar cell directly and solar energy cannot be used effectively. If the TCO layer has an irregular texture, the light scattering level is enhanced to increase the chance of absorbing the light. However, if the back TCO layer of the thin film silicon solar cell with the superstrate structure has a texture surface, it is necessary to submerge the whole thin film silicon solar cell into an acid solution. Since the environmental control of the process is not easy, the process may scrap the whole thin film silicon solar cell.

Based on the aforementioned problem, manufactures urgently require a thin film silicon solar cell and a manufacturing method of the thin film solar cell capable of reflecting an incident light from a metal layer to enhance the power generation efficiency of the thin film solar cell.

### SUMMARY OF THE INVENTION

The present invention provides a thin film silicon solar cell, comprising a glass substrate, a first electrode layer, a light absorbing layer, a second electrode layer, and a metal electrode layer sequentially stacked on top of one another, wherein the second electrode layer has a texture surface and a plurality of concavities formed on the texture surface, and each concavity has a width falling within a range of 100 nm-1600 nm and a depth less than 800 nm.

Therefore, it is a primary objective of the present invention to provide a thin film silicon solar cell, wherein the second electrode layer is etched to form a texture surface, and the texture surface of the second electrode layer is provided to increase the number of reflection paths of the incident light in order to improve the chance of absorbing the incident light and increase the short-circuit current density.

Another objective of the present invention is to provide a thin film silicon solar cell, wherein the second electrode layer is etched to form a texture surface, and the texture surface can reflect an incident light of a greater wavelength to achieve the effect of improving the power generation efficiency.

The present invention further provides a manufacturing method of a thin film silicon solar cell, comprising the steps of: providing a glass substrate; forming a first electrode layer on the glass substrate; forming a light absorbing layer on the first electrode layer; forming a second electrode layer on the light absorbing layer; etching the second electrode layer to form a texture surface on the second electrode layer, and the texture surface having a plurality of concavities; and forming a metal layer on the texture surface of the second electrode layer.

It is another objective of the present invention to provide a manufacturing method of a thin film silicon solar cell, wherein the second electrode layer is etched to form a texture surface, and the texture surface increases the number of reflection paths to achieve the effects of improving the chance of absorbing the incident light and increasing the short-circuit current density and the power generation efficiency.

Another objective of the present invention is to provide a manufacturing method of a thin film silicon solar cell, wherein the second electrode layer is etched to form a texture surface, and the texture surface can reflect an incident light of a greater wavelength to improve the power generation efficiency.

### BRIEF DESCRIPTION OF THE DRAWINGS

FIG. 1 is a schematic view of a thin film silicon solar cell in accordance with a first preferred embodiment of the present invention;

FIG. 2A is a SEM image of a second electrode layer without a texture surface;

FIG. 2B is a SEM image of a second electrode layer with a texture surface;

FIG. 3 is a comparison graph of wavelength versus external quantum efficiency, comparing thin film silicon solar cells having a second electrode layer with and without a texture surface; and

FIG. 4 is a schematic view showing a manufacturing method of a thin film silicon solar cell in accordance with a second preferred embodiment of the present invention.

### DESCRIPTION OF THE PREFERRED EMBODIMENTS

Since both thin film material and electrode material of the thin film silicon solar cell and the manufacturing method thereof are prior arts, therefore they will not be described here. The technical characteristics and effects of the present invention will become apparent by the detailed description of preferred embodiments and the illustration of related drawings as follows. For simplicity, same numerals are used for representing respective elements respectively in the following preferred embodiments and drawings.

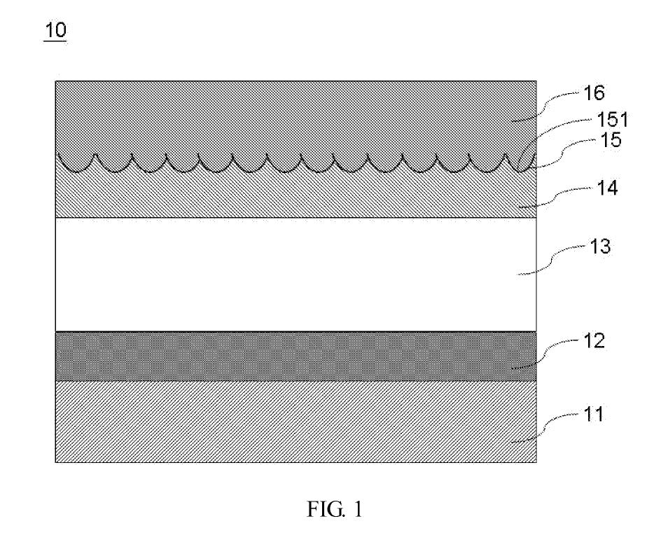

With reference to FIG. 1 for a thin film silicon solar cell 10 in accordance with the first preferred embodiment of the present invention, the thin film silicon solar cell 10 comprises a glass substrate 11, a first electrode layer 12, a light absorbing layer 13, a second electrode layer 14 and a metal layer 16, sequentially stacked on top of one another. The second electrode layer 14 has a texture surface 15, and the texture surface 15 has a plurality of concavities 151. The texture surface 15 is formed by etching, wherein less than 1% of a dilute hydrochloric acid solution is used for the etching conducted at room temperature for less than 5 minutes.

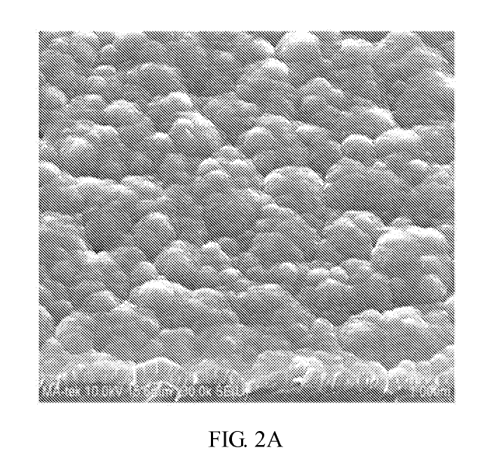

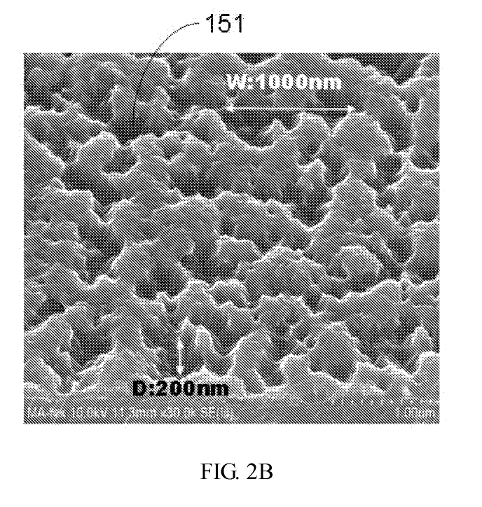

With reference to FIG. 2A for a SEM image of the second electrode layer 14 without the texture surface 15 before the etching takes place, the SEM image shows that the second electrode layer 14 has a smooth and flat surface. With reference to FIG. 2B for a SEM image of the second electrode layer 14 with the texture surface 15 after the etching takes place, the SEM image shows that the texture surface 15 has a plurality of concavities 151. Each of the concavities 151 of the texture surface 15 has a width W falling within a range from 100 nm to 1600 nm, and preferably a width falling within a range from 300 nm to 400 nm. The concavity 151 of the texture surface 15 has a depth D less than 800 nm and preferably a depth falling within a range from 150 nm to 200 nm. The concavities 151 are provided for reflecting the incident light of a greater wavelength such as the wavelength falling within a range from 500 nm to 1200 nm to achieve the effect of improving the power generation efficiency.

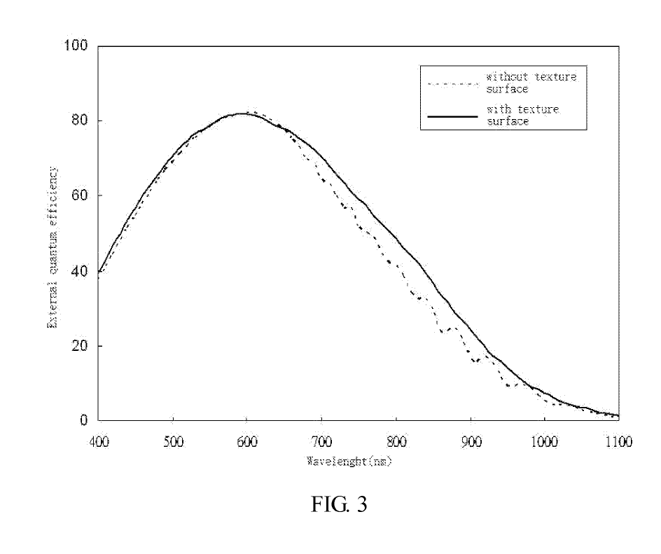

To compare the difference between the thin film silicon solar cell 10 having the second electrode layer 14 without the texture surface 15 and the thin film silicon solar cell 10 having the second electrode layer 14 with the texture surface 15, the short-circuit current densities (Jsc) of the two are measured in unit of mA/cm². The average short-circuit current density of the thin film silicon solar cell 10 having the second electrode layer 14 without the texture surface 15 is equal to 19.95 mA/cm², and the average short-circuit current density of the thin film silicon solar cell 10 having the second electrode layer 14 with the texture surface 15 is equal to 21.30 mA/cm². Obviously, the results show that the thin film silicon solar cell 10 having the second electrode layer 14 with the texture surface 15 can increase the number of reflection paths of the incident light to improve the chance of absorbing the incident light and increase the short-circuit current density. With reference to FIG. 3 for a comparison graph of wavelength versus external quantum efficiency (EQE), comparing thin film silicon solar cells 10 having a second electrode layer 14 with and without a texture surface 15, the experiment results show that the thin film silicon solar cell 10 having the second electrode layer 14 with the texture surface 15 can reflect an incident light of a greater wavelength to achieve the effect of improving the power generating efficiency.

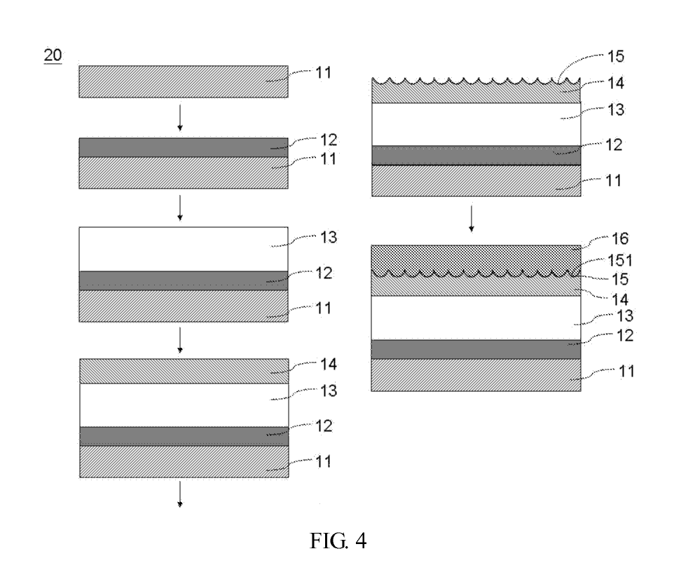

With reference to FIG. 4 for a manufacturing method of a thin film silicon solar cell 20 in accordance with the second preferred embodiment of the present invention, the manufacturing method of a thin film silicon solar cell 20 comprises the steps of:

(1) providing a glass substrate 11;

(2) forming a first electrode layer 12 on the glass substrate 11;

(3) forming a light absorbing layer 13 on the first electrode layer 12;

(4) forming a second electrode layer 14 on the light absorbing layer 13;

(6) etching the second electrode layer 14 to form a texture surface 15 having a plurality of concavities 151;

(7) forming a metal layer 16 on the irregular texture surface 15 of the second electrode layer 14; and

(8) performing a heat treatment of the second electrode layer 14 to dry the second electrode layer 14.

Wherein, the texture surface 15 as described in the step (5) is formed by etching, and the etching is conducted at room temperature, and less than 1% of a dilute hydrochloric acid solution is used for the etching, and the etching time is less than 5 minutes. Each of the concavities 151 of the texture surface 15 has a width W falling within a range from 100 nm to 1600 nm and a depth D less than 800 nm, and preferably, the concavity 151 has a width falling within a range from 300 nm to 400 nm and a depth falling within a range from 150 nm to 200 nm. The concavities 151 are provided for reflecting an incident light with a greater wavelength such as the incident light with a reflection wavelength falling within a range from 500 nm to 1200 nm to achieve the effect of improving the power generation efficiency.

What is claimed is:

1. A thin film silicon solar cell, comprising a glass substrate, a first electrode layer, a light absorbing layer, a second electrode layer and a metal layer, sequentially stacked on top of one another, characterized in that the second electrode layer has a texture surface, and the texture surface has a plurality of concavities, and each of the concavities has a width falling within a range from 100 nm to 1600 nm and a depth less than 800 nm.

2. The thin film silicon solar cell of claim 1, wherein the texture surface is formed by etching, and less than 1% of a dilute hydrochloric acid solution is used for the etching conducted at room temperature for less than 5 minutes.

3. The thin film silicon solar cell of claim 1, wherein the concavities of the texture surface are used for reflecting an incident light with a wavelength falling within a range from 500 nm to 1200 nm.

4. The thin film silicon solar cell of claim 2, wherein each of the concavities of the texture surface has a width preferably falling within a range from 300 nm to 400 nm.

5. The thin film silicon solar cell of claim 2, wherein each of the concavities of the texture surface has a depth preferably falling within a range from 150 nm to 200 nm.

6. A manufacturing method of a thin film silicon solar cell, comprising the steps of:
providing a glass substrate;
forming a first electrode layer on the glass substrate;
forming a light absorbing layer on the first electrode layer;
forming a second electrode layer on the light absorbing layer;
etching the second electrode layer to form a texture surface on the second electrode layer, and the texture surface having a plurality of concavities; and
forming a metal layer on the texture surface of the second electrode layer.

7. The manufacturing method of a thin film silicon solar cell of claim 6, wherein each of the concavities of the texture surface has a width falling within a range from 100 nm to 1600 nm and a depth less than 800 nm.

8. The manufacturing method of a thin film silicon solar cell of claim 6, wherein less than 1% of a dilute hydrochloric acid solution is used for the etching conducted at room temperature for less than 5 minutes.

9. The manufacturing method of a thin film silicon solar cell of claim 8, further comprising a heat treatment for drying the second electrode layer.
